(19) United States
(12) Patent Application Publication
(10) Pub. No.: US 2019/0277572 A1
(43) Pub. Date: Sep. 12, 2019

(54) PHASE-CHANGE COOLING APPARATUS AND PHASE-CHANGE COOLING METHOD

(71) Applicant: NEC Corporation, Tokyo (JP)

(72) Inventors: Arihiro MATSUNAGA, Tokyo (JP); Minoru YOSHIKAWA, Tokyo (JP); Masaki CHIBA, Tokyo (JP); Hisato SAKUMA, Tokyo (JP); Masanori SATO, Tokyo (JP); Mizuki WADA, Tokyo (JP); Koichi TODOROKI, Tokyo (JP)

(73) Assignee: NEC Corporation, Tokyo (JP)

(21) Appl. No.: 16/335,164

(22) PCT Filed: Sep. 15, 2017
(86) PCT No.: PCT/JP2017/033426

§ 371 Date: Mar. 20, 2019

(30) Foreign Application Priority Data
Sep. 21, 2016 (JP) 2016-184363

(51) Int. Cl. F28D 15/02; G06F 1/20; H05K 7/20

(52) U.S. Cl. CPC F28D 15/0266; G06F 1/20; F28D 15/0275; G06F 2200/201; H05K 7/20318; H05K 7/20327; H05K 7/20309

(57) ABSTRACT

A phase-change cooling apparatus according to an exemplary aspect of the present invention includes an evaporator a condenser; a refrigerant liquid driving means for circulating the refrigerant liquid; a first piping section configured to connect the evaporator and the condenser; a second piping section configured to connect the condenser to the refrigerant liquid driving means; a third piping section configured to connect the refrigerant liquid driving means to the evaporator; a refrigerant pooling means for pooling the refrigerant liquid, the refrigerant pooling means being located in a flow path constituted by the second piping section; and a fourth piping section, with one end of the fourth piping section connected to the first piping section at a first connecting point, and another end of the fourth piping section connected to the refrigerant pooling means at a second connecting point.

### TECHNICAL FIELD

The present invention relates to phase-change cooling apparatuses and phase-change cooling methods used in a datacenter and the like, and, in particular, to a phase-change cooling apparatus and a phase-change cooling method in which refrigerant liquid is circulated using a drive source.

### BACKGROUND ART

A refrigerant forced-circulation cooling system has been known in which refrigerant liquid is circulated using a drive source such as a pump, and heat is transported to the outside of a room using a temperature difference between the inside of the room and an outdoor unit. In the refrigerant forced-circulation cooling system, refrigerant liquid is constantly supplied to a heat receiving unit by a pump and receives heat in the heat receiving unit, and the refrigerant liquid inside the heat receiving unit vaporizes and accordingly draws the heat. The vaporized refrigerant moves to the outdoor unit through piping and then releases the heat at the outdoor unit, thereby transports the heat and cools the air inside the room. Thus, with such a phase-change cooling system using phase change of refrigerant, a cooling apparatus with high cooling capacity is achieved.

An example of the above-mentioned refrigerant forced-circulation cooling system using the phase-change cooling system is described in Patent Literature 1 (PTL 1). The related cooling system described in PTL 1 includes a primary system including a primary heat transfer pipe of a condenser, and a secondary system including a secondary heat transfer pipe of the condenser, a refrigerant liquid tank, a refrigerant pump, and an evaporator.

The condenser condenses medium-temperature refrigerant gas flowing into the secondary heat transfer pipe from the evaporator through piping, by cooling the refrigerant gas using cold water flowing into the primary heat transfer pipe. The secondary heat transfer pipe of the condenser is connected to an upper portion of the refrigerant liquid tank through piping.

The refrigerant liquid tank stores liquid-state refrigerant flowing into it from the condenser, and is located lower than the condenser. A lower portion of the refrigerant liquid tank is connected to an inlet of the refrigerant pump through piping. Inside the refrigerant liquid tank, liquid level sensors S1 and S2 are provided that detects whether or not the level of the refrigerant liquid stored in the refrigerant liquid tank is equal to or higher than a predetermined height.

Here, the liquid level sensor S1 outputs an ON signal to a control device when the refrigerant liquid level is equal to or higher than a height H1, and outputs an OFF signal to the control device when the refrigerant liquid level is lower than the height H1. On the other hand, the liquid level sensor S2 is located at a higher position (height H2) than the height H1 at which the liquid level sensor S1 is located. Here, the liquid level sensor S2 outputs an ON signal to the control device when the refrigerant liquid level is equal to or higher than the height H2, and outputs an OFF signal to the control device when the refrigerant liquid level is lower than the height H2.

The control device stops the refrigerant pump when the signal from the liquid level sensor S1 becomes the OFF signal, and starts driving again the refrigerant pump when the signal from the liquid level sensor S2 subsequently becomes the ON signal.

It is described in PTL 1 that, by employing such a configuration, the related cooling system (phase-change cooling apparatus) makes it possible to securely prevent failure of the refrigerant pump due to dry running or cavitation and accordingly increase reliability of the facility.

Related art technologies are also described in Patent Literature 2 (PTL 2) to Patent Literature 4 (PTL 4).

### CITATION LIST

### Patent Literature

[PTL 1] Japanese Patent Application Laid-Open Publication No. 2013-088027 (paragraphs [0012] to [0041], FIG. 1)

[PTL 2] Japanese Patent Application Laid-Open Publication No. H11-182972

[PTL 3] Japanese Patent Application Laid-Open Publication No. H6-082182

[PTL 4] Japanese Patent Application Laid-Open Publication No. H6-001300

### SUMMARY OF INVENTION

### Technical Problem

As mentioned above, the related cooling system (phase-change cooling apparatus) is configured to control the operation of the refrigerant pump according to the output signals from the two liquid level sensors. Accordingly, there has been the problem that the control of the whole apparatus becomes complicated.

As mentioned above, in a phase-change cooling apparatus in which refrigerant liquid is circulated using a drive source, there has been the problem that the reliability of the apparatus is difficult to improve without employing a complex control.

The objective of the present invention is to provide a phase-change cooling apparatus and a phase-change cooling method that solve the above-mentioned problem that, in a phase-change cooling apparatus in which refrigerant liquid is circulated using a drive source, the reliability of the apparatus is difficult to improve without employing a complex control.

### Solution to Problem

A phase-change cooling apparatus according to an exemplary aspect of the present invention includes an evaporator configured to hold refrigerant liquid to receive heat from a heat generating source; a condenser configured to release heat of refrigerant vapor produced by evaporation of the refrigerant liquid in the evaporator, thereby producing refrigerant liquid; a refrigerant liquid driving means for circulating the refrigerant liquid; a first piping section configured to connect the evaporator and the condenser; a second piping section configured to connect the condenser to the refrigerant liquid driving means; a third piping section configured to connect the refrigerant liquid driving means to the evaporator; a refrigerant pooling means for pooling the refrigerant liquid, the refrigerant pooling means being located in a flow path constituted by the second piping section; and a fourth piping section, with one end of the fourth piping section connected to the first piping section at a first connecting point, and another end of the fourth piping section connected to the refrigerant pooling means at a second connecting point.

A phase-change cooling method according to an exemplary aspect of the present invention includes circulating refrigerant liquid through a first flow path flowing back through a heat receiving region; producing condensed refrigerant liquid by condensing refrigerant vapor included in a vapor-liquid two-phase refrigerant, when the vapor-liquid two-phase refrigerant is produced as a result of heat receiving by the refrigerant liquid in the heat receiving region; and circulating the condensed refrigerant liquid through a second flow flowing back through the heat receiving region, wherein a length of the first flow path is shorter than a length of the second flow path.

### Advantageous Effects of Invention

According to the phase-change cooling apparatus and the phase-change cooling method of the present invention, even employing a configuration in which refrigerant liquid is circulated using a drive source, the reliability of the apparatus can be increased without making the control complicated.

### BRIEF DESCRIPTION OF DRAWINGS

FIG. 1 is a schematic view illustrating a configuration of a phase-change cooling apparatus according to a first example embodiment of the present invention.

FIG. 2 is a schematic view for explaining the configuration of the phase-change cooling apparatus according to the first example embodiment of the present invention.

FIG. 3 is a schematic view for explaining the configuration of the phase-change cooling apparatus according to the first example embodiment of the present invention.

FIG. 4 is a schematic view illustrating a configuration of a phase-change cooling apparatus according to a second example embodiment of the present invention.

### EXAMPLE EMBODIMENT

Example embodiments of the present invention will be described with reference to drawings below.

### First Example Embodiment

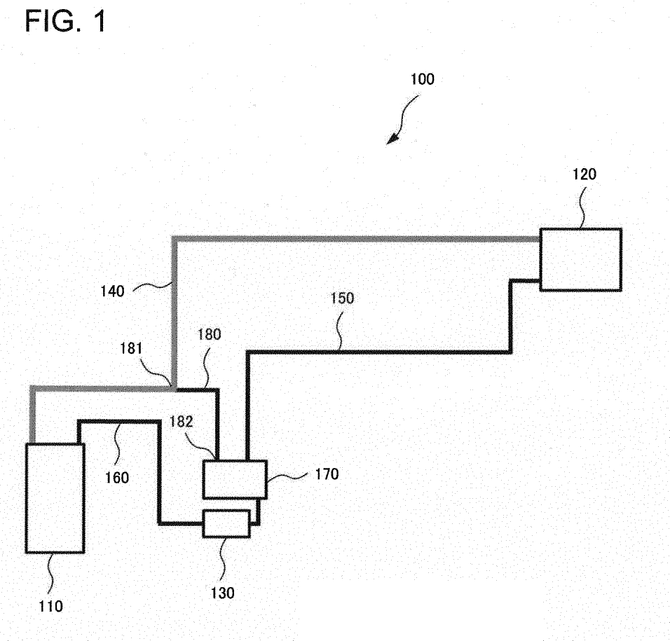

FIG. 1 is a schematic view illustrating a configuration of a phase-change cooling apparatus 100 according to a first example embodiment of the present invention. The phase-change cooling apparatus 100 according to the present example embodiment includes an evaporator 110, a condenser 120, a refrigerant liquid driving section (refrigerant liquid driving means) 130, a first piping section 140, a second piping section 150, a third piping section 160, a refrigerant pooling section (refrigerant pooling means) 170, and a fourth piping section 180.

The evaporator 110 holds refrigerant liquid to receive heat from a heat generating source. The evaporator 110 is typically constituted by a radiator or the like, and is installed inside a room of a datacenter to accommodate a server or the like that serves as a heat generating source, for example. The condenser 120 releases heat of refrigerant vapor produced by evaporation of the refrigerant liquid in the evaporator 110, thereby producing refrigerant liquid. The condenser 120 is typically constituted by a heat exchanger, an outdoor unit or the like. The refrigerant liquid driving section 130 circulates the refrigerant liquid. The refrigerant liquid driving section 130 is typically constituted by a pump or the like and supplies the refrigerant liquid to the evaporator 110.

The first piping section 140 connects the evaporator 110 and the condenser 120. The second piping section 150 connects the condenser 120 and the refrigerant liquid driving section 130. The third piping section 160 connects the refrigerant liquid driving section 130 and the evaporator 110.

Here, the refrigerant pooling section 170 is located in a flow path constituted by the second piping section 150. The refrigerant pooling section 170 is typically constituted by a metal container such as a tank. One end of the fourth piping section 180 is connected to the first piping section 140 at a first connecting point 181, and the other end of the fourth piping section 180 is connected to the refrigerant pooling section 170 at a second connecting point 182.

The first piping section 140, the second piping section 150, the third piping section 160, and the fourth piping section 180 are each typically made of a metal pipe or the like.

The above-described configuration makes a flow path through which refrigerant liquid constantly circulates formed in the phase-change cooling apparatus 100 according to the present example embodiment.

Specifically, when no heat load is applied to the evaporator 110, the refrigerant liquid supplied from the refrigerant liquid driving section 130 to the heat receiving unit 110 flows into the refrigerant pooling section 170 passing through the first piping section 140 and the fourth piping section 180. The refrigerant liquid is subsequently supplied again to the evaporator 110 by the refrigerant liquid driving section 130; consequently, the refrigerant liquid circulates.

As described above, a first flow path is formed that circulates through the refrigerant liquid driving section 130 (a pump), the evaporator 110, the first piping section 140, the fourth piping section 180, and the refrigerant pooling section 170 (a tank). This makes it unnecessary to supply refrigerant liquid constantly to the condenser 120 installed outside the room, for example. That is to say, even though the condenser 120 is installed at a point distant from the evaporator 110, it is unnecessary to fill the first piping section 140 ranging from the first connecting point 181 to the condenser 120 with a large quantity of refrigerant liquid. As a result, it becomes possible to reduce the amount of refrigerant liquid and achieve cost reduction.

On the other hand, if heat load is applied to the evaporator 110, part of the refrigerant liquid held in the evaporator 110 vaporizes and turns into vapor-liquid two-phase refrigerant, which causes the heat to be drawn. The refrigerant vapor included in the vapor-liquid two-phase refrigerant moves to the condenser 120 through the first piping section 140. The refrigerant vapor is cooled in the condenser 120; consequently, it is condensed and liquefied, and releases the heat; accordingly, it turns into condensed refrigerant liquid and flows into the refrigerant pooling section 170 through the second piping section 150. The condensed refrigerant liquid is supplied again to the evaporator 110 by the refrigerant liquid driving section 130, which causes a second flow path through which refrigerant liquid circulates to be constituted.

As described above, according to the phase-change cooling apparatus 100 of the present example embodiment, it is possible to have a configuration in which refrigerant liquid is constantly circulating regardless of whether or not heat load is applied to the evaporator 110.

Accordingly, it becomes unnecessary to control opening and closing of a valve, the operation of a pump, and the like in order to detect heat load and accordingly adjust the amount of refrigerant liquid to be supplied. As a result, it becomes possible to securely prevent failure of the refrigerant liquid driving section 130 (pump) caused by dry running or occurrence of cavitation due to exhaustion of the refrigerant liquid, without making the control complicated. That is to say, according to the phase-change cooling apparatus 100 of the present example embodiment, even employing a configuration in which refrigerant liquid is circulated using a drive source, the reliability of the apparatus can be increased without making the control complicated.

The refrigerant pooling section 170 can be located lower than the first connecting point 181. This enables excess refrigerant liquid, which is refrigerant liquid included in the vapor-liquid two-phase refrigerant within the first piping section 140, to move to the refrigerant pooling section 170 through the fourth piping section 180 by the action of gravity. As a result, it becomes possible to prevent it that the condensation of the refrigerant vapor is hindered by mixture of the excess refrigerant liquid into the condenser 120, and that the performance of the condenser 120 decreases accordingly.

The refrigerant pooling section 170 can be located higher than the refrigerant liquid driving section 130. In that case, the refrigerant pooling section 170 can be located away from a pump constituting the refrigerant liquid driving section 130 by a distance that enables provision of a suction pressure in normal operation of the pump. This makes it possible to secure Net Positive Suction Head (NPSH) for the pump and accordingly avoid a decrease in the efficiency of the pump due to the cavitation.

In addition, the condenser 120 can be located higher than the evaporator 110, and the first connecting point 181 can be located higher than the evaporator 110 and lower than the condenser 120. This makes it easy for the refrigerant vapor within the first piping section 140 to move to the condenser 120 by buoyancy. On the other hand, the excess refrigerant liquid that is the refrigerant liquid included in the vapor-liquid two-phase refrigerant is prevented from moving to the condenser 120 by the action of gravity, and easily moves to the refrigerant pooling section 170 through the fourth piping section 180. As a result, a circulating flow of the refrigerant in the phase-change cooling apparatus 100 becomes smooth; accordingly, the cooling performance can be improved.

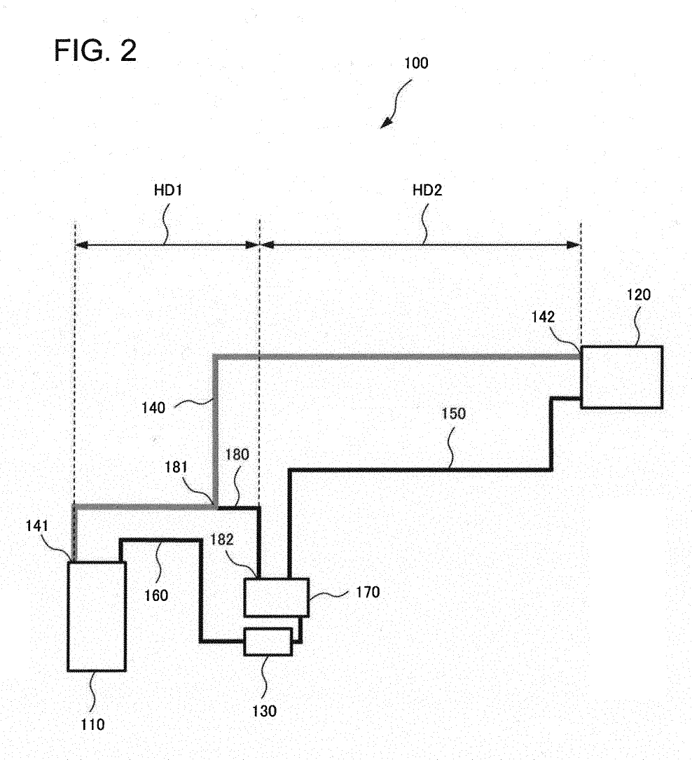

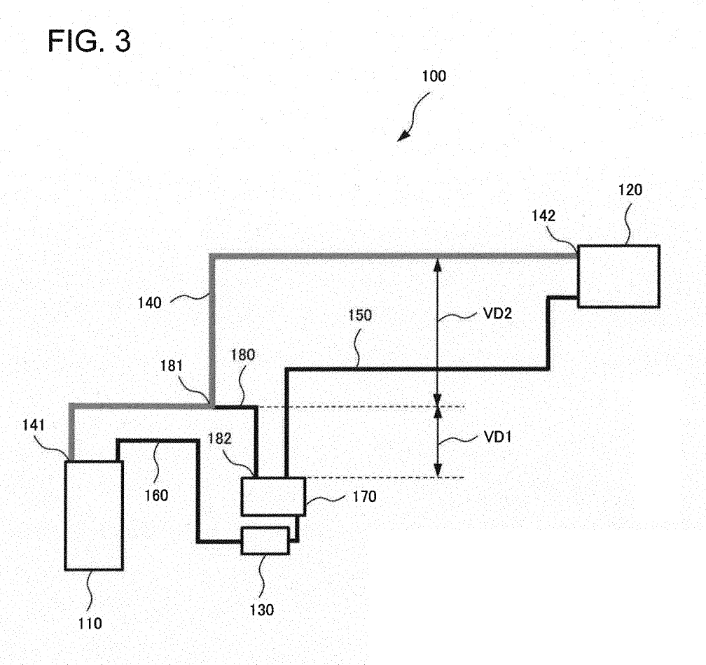

Next, the configurations of the phase-change cooling apparatus 100 according to the present example embodiment will be described further in detail using FIG. 2 and FIG. 3. FIG. 2 and FIG. 3 are schematic views for explaining the configurations of the phase-change cooling apparatus 100 according to the present example embodiment.

As shown in FIG. 2, the phase-change cooling apparatus 100 according to the present example embodiment can be configured such that a first horizontal piping distance HD1 is shorter than a second horizontal piping distance HD2. Here, the first horizontal piping distance HD1 is a horizontal distance of a connecting location 141, where the first piping section 140 is connected to the evaporator 110, to the second connecting point 182. The second horizontal piping distance HD2 is a horizontal distance of a connecting location 142, where the first piping section 140 is connected to the condenser 120, to the second connecting point 182.

As shown in FIG. 3, the phase-change cooling apparatus 100 according to the present example embodiment can also be configured such that a first vertical piping distance VD1 is shorter than a second vertical piping distance VD2. Here, the first vertical piping distance VD1 is a vertical distance between the first connecting point 181 and the second connecting point 182. The second vertical piping distance VD2 is a vertical distance of the connecting location 142, where the first piping section 140 is connected to the condenser 120, to the first connecting point 181.

Those configurations enable the length of the above-mentioned first flow path to be reduced. That is to say, it is possible to reduce the length of the first flow path through which the refrigerant liquid supplied from the refrigerant liquid driving section 130 to the heat receiving unit 110 flows into the refrigerant pooling section 170 passing through the first piping section 140 and the fourth piping section 180, and flows back to the evaporator 110 again by the refrigerant liquid driving section 130. As a result, it becomes possible to further reduce the amount of the refrigerant liquid with which the phase-change cooling apparatus 100 is filled and accordingly achieve further cost reduction.

Next, a phase-change cooling method according to the present example embodiment will be described.

In the phase-change cooling method according to the present example embodiment, first, refrigerant liquid is circulated through a first flow path flowing back through a heat receiving region. When a vapor-liquid two-phase refrigerant is produced as a result of heat receiving by the refrigerant liquid in the heat receiving region, a condensed refrigerant liquid is produced by condensing a refrigerant vapor included in the vapor-liquid two-phase refrigerant. The condensed refrigerant liquid is circulated through a second flow flowing back through the heat receiving region. The length of the first flow path is shorter than that of the second flow path.

As described above, in the phase-change cooling method according to the present example embodiment, the refrigerant liquid is constantly circulated. Accordingly, the phase-change cooling method of the present example embodiment makes it possible to increase reliability of the cooling action without making the control complicated. The length of the first flow path for circulating the refrigerant liquid only is shorter than the length of the second flow path for circulating the condensed refrigerant liquid produced by condensing the refrigerant vapor. This makes it possible to reduce the amount of the refrigerant liquid to be used and accordingly achieve cost reduction.

In addition, the phase-change cooling method according to the present example embodiment may be configured such that an excess refrigerant liquid that is a refrigerant liquid included in the vapor-liquid two-phase refrigerant is extracted from the vapor-liquid two-phase refrigerant, the condensed refrigerant liquid is mixed with the excess refrigerant liquid, and then the condensed refrigerant liquid is returned to the heat receiving region through the second flow path. This makes it possible to prevent a decrease in the cooling performance caused by the fact that the excess refrigerant liquid hinders the refrigerant vapor from condensing.

### Second Example Embodiment

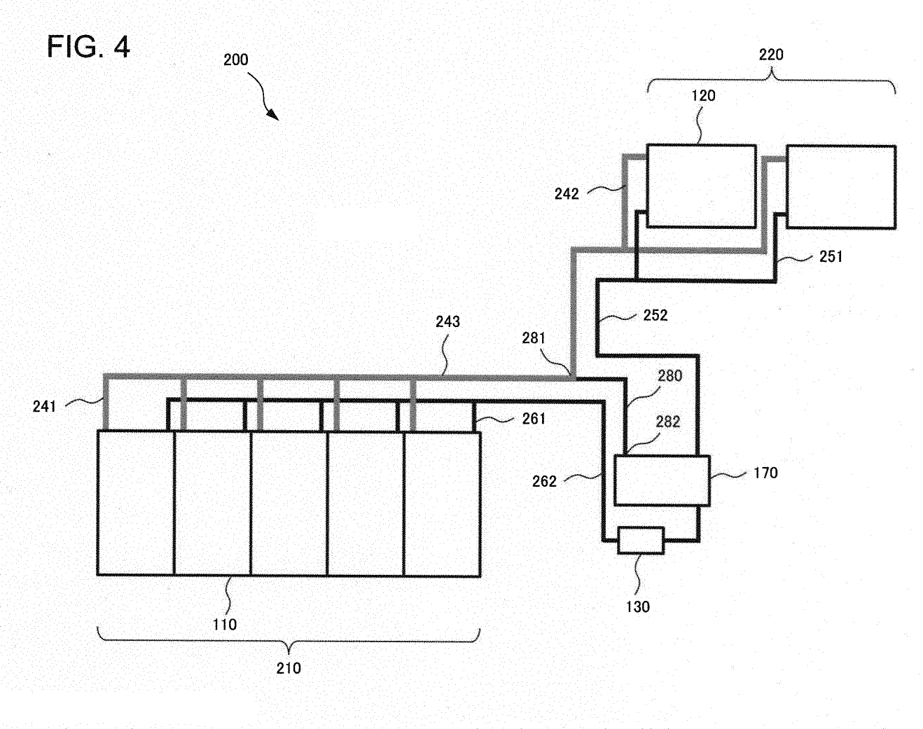

Next, a second example embodiment of the present invention will be described. FIG. 4 schematically illustrates a configuration of a phase-change cooling apparatus 200 according to the second example embodiment of the present invention.

The configuration of the phase-change cooling apparatus 200 according to the present example embodiment differs from that of the phase-change cooling apparatus 100 according to the first example embodiment in including an evaporation section 210 including a plurality of evaporators 110. A first piping section is configured to include a plurality of evaporator-side pipes 241 connected respectively to the plurality of evaporators 110, a condenser-side pipe 242 connected to the condenser 120, and a common pipe 243 connected to each of the plurality of evaporator-side pipes 241 and to the condenser-side pipe 242. In addition, a fourth piping section 280 is configured to be connected to the first piping section at a first connecting point 281 of the common pipe 243, and to the refrigerant pooling section 170 at a second connecting point 282.

The other configurations are similar to those of the phase-change cooling apparatus 100 according to the first example embodiment; accordingly, their descriptions will not be repeated.

As described above, because the phase-change cooling apparatus 200 according to the present example embodiment is configured to include the evaporation section 210 including the plurality of evaporators 110, it becomes possible to cool a plurality of heat generating sources efficiently. In this case, according to the phase-change cooling apparatus 200 of the present example embodiment, even employing a configuration in which refrigerant liquid is circulated using a drive source, the reliability of the apparatus can also be increased without making the control complicated.

In addition, the phase-change cooling apparatus 200 according to the present example embodiment may be configured to include a condensation section 220 including a plurality of condensers 120, as shown in FIG. 4. In this case, a second piping section can be configured to include a plurality of second evaporator-side pipes 251 connected respectively to the plurality of condensers 120, and a second common pipe 252 connecting the plurality of condenser-side pipes 251 to the refrigerant pooling section 170. A third piping section can be also configured to include a plurality of third evaporator-side pipes 261 connected respectively to the plurality of evaporators 110, and a third common pipe 262 connecting the plurality of third evaporator-side pipes 261 to the refrigerant liquid driving section 130.

Those configurations enable the cooling performance of the phase-change cooling apparatus 200 to improve further.

While the invention has been particularly shown and described with reference to example embodiments thereof, the invention is not limited to these example embodiments. It will be understood by those of ordinary skill in the art that various changes in form and details may be made therein without departing from the spirit and scope of the present invention as defined by the claims.

This application is based upon and claims the benefit of priority from Japanese patent application No. 2016-184363 filed on Sep. 21, 2016, the disclosure of which is incorporated herein in its entirety by reference.

### REFERENCE SIGNS LIST

100, 200 phase-change cooling apparatus
110 evaporator
120 condenser
130 refrigerant liquid driving section
140 first piping section
150 second piping section
160 third piping section
170 refrigerant pooling section
180, 280 fourth piping section
181, 281 first connecting point
182, 282 second connecting point
210 evaporation section
220 condensation section
241 evaporator-side pipe
242 condenser-side pipe
243 common pipe
251 second condenser-side pipe
252 second common pipe
261 third evaporator-side pipe
262 third common pipe
HD1 first horizontal piping distance
HD2 second horizontal piping distance
VD1 first vertical piping distance
VD2 second vertical piping distance

1: A phase-change cooling apparatus, comprising:
an evaporator configured to hold refrigerant liquid to receive heat from a heat generating source;
a condenser configured to release heat of refrigerant vapor produced by evaporation of the refrigerant liquid in the evaporator, thereby producing refrigerant liquid;
a refrigerant liquid driving section configured to circulate the refrigerant liquid;
a first piping section configured to connect the evaporator and the condenser;
a second piping section configured to connect the condenser to the refrigerant liquid driving section;
a third piping section configured to connect the refrigerant liquid driving section to the evaporator;
a refrigerant pooling section configured to pool the refrigerant liquid, the refrigerant pooling section being located in a flow path constituted by the second piping section; and
a fourth piping section, with one end of the fourth piping section connected to the first piping section at a first connecting point, and another end of the fourth piping section connected to the refrigerant pooling section at a second connecting point.

2: The phase-change cooling apparatus according to claim 1, wherein
a first horizontal piping distance that is a horizontal distance of a connecting location where the first piping section is connected, to the evaporator to the second connecting point, is shorter than a second horizontal piping distance that is a horizontal distance of a connecting location where the first piping section is connected, to the condenser to the second connecting point.

3: The phase-change cooling apparatus according to claim 1, wherein
a first vertical piping distance that is a vertical distance between the first connecting point and the second connecting point is shorter than a second vertical piping distance that is a vertical distance of a connecting location where the first piping section is connected to the condenser, to the first connecting point.

4: The phase-change cooling apparatus according to claim 1, wherein
the refrigerant pooling section is located lower than the first connecting point.

5: The phase-change cooling apparatus according to claim 1, wherein
the refrigerant pooling section is located higher than the refrigerant liquid driving section.

6: The phase-change cooling apparatus according to claim 5, wherein
the refrigerant liquid driving section is a pump, and
the refrigerant pooling section is located away from the pump by a distance that enables provision of a suction pressure in normal operation of the pump.

7: The phase-change cooling apparatus according to claim 1, wherein
the condenser is located higher than the evaporator, and
the first connecting point is located higher than the evaporator and lower than the condenser.

8: The phase-change cooling apparatus according to claim 1, further comprising an evaporation section including a plurality of evaporators,
wherein the first piping section includes a plurality of evaporator-side pipes connected respectively to the plurality of evaporators, a condenser-side pipe connected to the condenser, and a common pipe connected to each of the plurality of evaporator-side pipes and to the condenser-side pipe, and
the fourth piping section is connected to the first piping section at the first connecting point of the common pipe.

9: A phase-change cooling method, comprising:
circulating refrigerant liquid through a first flow path flowing back through a heat receiving region;
producing condensed refrigerant liquid by condensing refrigerant vapor included in a vapor-liquid two-phase refrigerant, when the vapor-liquid two-phase refrigerant is produced as a result of heat receiving by the refrigerant liquid in the heat receiving region; and
circulating the condensed refrigerant liquid through a second flow flowing back through the heat receiving region,
wherein a length of the first flow path is shorter than a length of the second flow path.

10: The phase-change cooling method according to claim 9, further comprising
extracting excess refrigerant liquid that is refrigerant liquid included in the vapor-liquid two-phase refrigerant from the vapor-liquid two-phase refrigerant, and
mixing the condensed refrigerant liquid with the excess refrigerant liquid and returning the condensed refrigerant liquid to the heat receiving region through the second flow path.

11: The phase-change cooling apparatus according to claim 2, wherein
a first vertical piping distance that is a vertical distance between the first connecting point and the second connecting point is shorter than a second vertical piping distance that is a vertical distance of a connecting location where the first piping section is connected to the condenser, to the first connecting point.

12: The phase-change cooling apparatus according to claim 2, wherein the refrigerant pooling section is located lower than the first connecting point.

13: The phase-change cooling apparatus according to claim 3, wherein the refrigerant pooling section is located lower than the first connecting point.

14: The phase-change cooling apparatus according to claim 2, wherein the refrigerant pooling section is located higher than the refrigerant liquid driving section.

15: The phase-change cooling apparatus according to claim 3, wherein
the refrigerant pooling section is located higher than the refrigerant liquid driving section.

16: The phase-change cooling apparatus according to claim 4, wherein
the refrigerant pooling section is located higher than the refrigerant liquid driving section.

17: The phase-change cooling apparatus according to claim 2, wherein
the condenser is located higher than the evaporator, and
the first connecting point is located higher than the evaporator and lower than the condenser.

18: The phase-change cooling apparatus according to claim 3, wherein
the condenser is located higher than the evaporator, and
the first connecting point is located higher than the evaporator and lower than the condenser.

19: The phase-change cooling apparatus according to claim 4, wherein
the condenser is located higher than the evaporator, and
the first connecting point is located higher than the evaporator and lower than the condenser.

20: The phase-change cooling apparatus according to claim 5, wherein
the condenser is located higher than the evaporator, and
the first connecting point is located higher than the evaporator and lower than the condenser.
